(19) United States
(12) Patent Application Publication
(10) Pub. No.: US 2025/0024678 A1
(43) Pub. Date: Jan. 16, 2025

(54) METHOD FOR MANUFACTURING THREE-DIMENSIONAL FLASH MEMORY ON BASIS OF STACKING PROCESS

(71) Applicant: IUCF-HYU (Industry-University Cooperation Foundation Hanyang University), Seoul (KR)

(72) Inventor: Yun Heub SONG, Seoul (KR)

(21) Appl. No.: 18/898,672

(22) Filed: Sep. 27, 2024

Related U.S. Application Data
(63) Continuation of application No. PCT/KR2023/004335, filed on Mar. 31, 2023.

(30) Foreign Application Priority Data
Apr. 5, 2022 (KR) 10-2022-0041978

(51) Int. Cl. H10B 43/27; H10B 51/20

(52) U.S. Cl. CPC H10B 43/27; H10B 51/20

(57) ABSTRACT

Disclosed is a method for manufacturing a three-dimensional flash memory on the basis of a stacking process. According to one embodiment, the method for manufacturing a three-dimensional flash memory may include the steps of: preparing stack structures which include interlayer insulation films and gate electrodes that extend in a horizontal direction and are alternately stacked in the vertical direction; forming channel holes and a capping layer, which includes a capping film, on at least one of the stack structures; stacking the remaining stack structures on top of the at least one stack structure; forming channel holes in the remaining stack structures and simultaneously removing the capping film in the at least one stack structure; and forming vertical channel structures in each of channel holes of a semiconductor structure in which the at least one stack structure and the remaining stack structures are stacked.

### TECHNICAL FIELD

The following embodiments relate to a technology for a three-dimensional flash memory and a method of manufacturing the same, and more particularly, to a manufacturing technology based on a stack process.

### BACKGROUND ART

A flash memory element that is an electrically erasable programmable read only memory (EEPROM) electrically controlling data input/output through an F-N (Fowler-Nordheim) tunneling or a hot electron injection may be used in common in a computer, a digital camera, an MP3 player, a game system, a memory stick, etc.

In this flash memory device, it is required to increase the degree of integration to satisfy excellent performance and low price demanded by consumers, and thus a three-dimensional structure in which memory cell transistors are vertically arranged to constitute a cell string has been proposed.

A stack process of stacking stack structures in a vertical direction is used to manufacture a three-dimensional flash memory.

As an example, referring to FIGS. 1A to 1E for describing a method of manufacturing a three-dimensional flash memory according to the related art, in a manufacturing system, a channel hole CH is formed in a first stack structure SS1 as illustrated in FIG. 1A, a filling film “F” is generated inside the channel hole CH as illustrated in FIG. 1B, a second stack structure SS2 including the filling film “F” is stacked on the first stack structure SS1, a third stack structure SS3 is stacked on the second stack structure SS2 so that the channel hole CH is formed in the third stack structure SS3 as illustrated in FIG. 1D, and then the filling film “F” of the first stack structure SS1 and the filling film “F” of the second stack structure SS2 are removed through the channel hole CH of the third stack structure SS3 as illustrated in FIG. 1E. Thus, the channel hole CH may be completely formed on a semiconductor structure SEMI-STR in which the stack structures SS1, SS2, and SS3 are stacked. Accordingly, although not separately illustrated in the drawing, the manufacturing system may manufacture a three-dimensional flash memory by forming a vertical channel structure VS inside the channel hole CH of the semiconductor structure SEMI-STR.

However, when the number of stack structures SS stacked in the vertical direction increases, difficulty of a process of collectively removing the filling film “F” of each of the stack structures located on the lower side through the channel hole CH of the stack structure located on the upper side increases.

Thus, a technology for solving the disadvantage of the method of manufacturing the three-dimensional flash memory according to the related art needs to be proposed.

### DETAILED DESCRIPTION OF THE INVENTION

### Technical Problem

To solve the disadvantage that difficulty of a process of collectively removing a filling film “F” of each of stack structures positioned on a lower side through a channel hole CH of a stack structure positioned on an upper side increases, embodiments propose a manufacturing method using a capping layer including a capping film having a size that is smaller than a size of the channel hole on a plane.

Further, embodiments propose a manufacturing method for connecting vertical channel structures of stack structures to each other such that an etching profile of the vertical channel structures of the stack structures is uniformly maintained using a capping layer including a capping film having a size that is smaller than a size of a channel hole on a plane.

However, technical problems to be solved by the present disclosure are not limited to the above problems and may be variously expanded without departing from the technical spirit and scope of the present disclosure.

### Technical Solution

According to an embodiment, a method of manufacturing a three-dimensional flash memory includes preparing stack structures including interlayer insulating films and gate electrodes formed to extend in a horizontal direction and alternately stacked in a vertical direction, forming channel holes and a capping layer including a capping film in at least one stack structure among the stack structures, stacking a remaining stack structure on the at least one stack structure, forming channel holes in the remaining stack structure, and at the same time, removing the capping film of the at least one stack structure, and forming vertical channel structures in channel holes of a semiconductor structure in which the at least one stack structure and the remaining stack structure are stacked.

According to an aspect, the capping film may be formed on the capping layer to have a size that is smaller than a size of each of the channel holes on a plane.

According to another aspect, the forming of the channel holes and the capping layer including the capping film in the at least one stack structure may include forming the channel holes in the at least one stack structure, forming a filling film in the channel holes, forming the capping layer on the at least one stack structure in which the filling film is formed, etching a partial area of the capping layer, the partial area having the size that is smaller than the size of each of the channel holes on a plane, removing the filling film through a space in which the partial area of the capping layer is etched, and forming the capping film in the space in which the partial area of the capping layer is etched such that the capping film has the size that is smaller than the size of each of the channel holes on a plane.

According to still another aspect, the etching of the partial area of the capping layer may include etching the partial area such that the space in which the partial area of the capping layer is etched has a negative profile, a positive profile, or a uniform profile.

According to yet another aspect, the forming of the filling film may include forming the filling film with a material removable through the space in which the partial area of the capping layer having the size that is smaller than the size of each of the channel holes on a plane is etched.

According to an embodiment, a method of manufacturing a three-dimensional flash memory includes preparing stack structures including interlayer insulating films and sacrificial layers formed to extend in a horizontal direction and alternately stacked in a vertical direction, forming channel holes and a capping layer including a capping film in at least one stack structure among the stack structures, stacking a remaining stack structure on the at least one stack structure, forming channel holes in the remaining stack structure, and at the same time, removing the capping film of the at least one stack structure, removing the sacrificial layers from a semiconductor structure in which the at least one stack structure and the remaining stack structure are stacked, forming gate electrodes in spaces in which the sacrificial layers are removed, and forming vertical channel structures in the channel holes of the semiconductor structure.

According to an aspect, the capping film may be formed on the capping layer to have a size that is smaller than a size of each of the channel holes on a plane.

According to another aspect, the forming of the channel holes and the capping layer including the capping film in the at least one stack structure may include forming the channel holes in the at least one stack structure, forming a filling film in the channel holes, forming the capping layer on the at least one stack structure in which the filling film is formed, etching a partial area of the capping layer, the partial area having the size that is smaller than the size of each of the channel holes on a plane, removing the filling film through a space in which the partial area of the capping layer is etched, and forming the capping film in the space in which the partial area of the capping layer is etched such that the capping film has the size that is smaller than the size of each of the channel holes on a plane.

According to still another aspect, the etching of the partial area of the capping layer may include etching the partial area such that the space in which the partial area of the capping layer is etched has a negative profile, a positive profile, or a uniform profile.

According to yet another aspect, the forming of the filling film may include forming the filling film with a material removable through the space in which the partial area of the capping layer having the size that is smaller than the size of each of the channel holes on a plane is etched.

According to an embodiment, a three-dimensional flash memory includes stack structures including interlayer insulating films and gate electrodes formed to extend in a horizontal direction and alternately stacked in a vertical direction and vertical channel structures formed to extend in the vertical direction while passing through the interlayer insulating films and the gate electrodes, the stack structures being stacked in the vertical direction, and a capping layer connecting the vertical channel structures of the stack structures to each other such that an etching profile of the vertical channel structures of the stack structures is uniformly maintained while being disposed between the stack structures.

According to an aspect, the capping layer may include a capping film having a size that is smaller than a size of each of channel holes included in each of the stack structures on a plane, connects the channel holes to each other as the capping film is removed in a process of etching the channel holes, and thus connects the vertical channel structures to each other while the etching profile of the vertical channel structures is uniformly maintained.

### Advantageous Effects of the Invention

Embodiments may propose a manufacturing method using a capping layer including a capping film having a size that is smaller than a size of a channel hole on a plane, thereby achieving a technical effect of omitting a process of collectively removing a filling film “F” of each of stack structures positioned on a lower side.

Further, embodiments may propose a manufacturing method for connecting vertical channel structures of stack structures to each other such that an etching profile of the vertical channel structures of the stack structures is uniformly maintained using a capping layer including a capping film having a size that is smaller than a size of a channel hole on a plane.

Thus, through embodiments, as vertical channel structures of stack structures are connected to each other, a technical effect that improves reliability and performance of a three-dimensional flash memory may be expected.

However, effects of the present disclosure are not limited to the above effects and may be variously expanded without departing from the technical spirit and scope of the present disclosure.

### DESCRIPTION OF THE DRAWINGS

FIGS. 1A to 1E are cross-sectional views illustrating a structure of a three-dimensional flash memory according to the related art for describing a method of manufacturing the three-dimensional flash memory according to the related art.

FIG. 2 is a schematic circuit diagram illustrating an array of the three-dimensional flash memory according to the embodiment.

FIG. 3 is a plan view illustrating the structure of the three-dimensional flash memory according to the embodiment.

FIG. 4 is a cross-sectional view illustrating the structure of the three-dimensional flash memory illustrated in FIG. 3 and corresponds to a cross section along line A-A′ of FIG. 3.

FIG. 5 is a flowchart illustrating the method of manufacturing the three-dimensional flash memory according to the embodiment in which a gate first method is applied to manufacture the three-dimensional flash memory illustrated in FIGS. 2 to 3.

FIGS. 6A to 6J are cross-sectional views illustrating the structure of the three-dimensional flash memory to describe the method of manufacturing the three-dimensional flash memory illustrated in FIG. 5.

FIG. 7 is a flowchart illustrating the method of manufacturing the three-dimensional flash memory according to the embodiment in which a word line replacement method is applied to manufacture the three-dimensional flash memory illustrated in FIGS. 2 to 3.

FIGS. 8A to 8L are cross-sectional views illustrating the structure of the three-dimensional flash memory to describe the method of manufacturing the three-dimensional flash memory illustrated in FIG. 7.

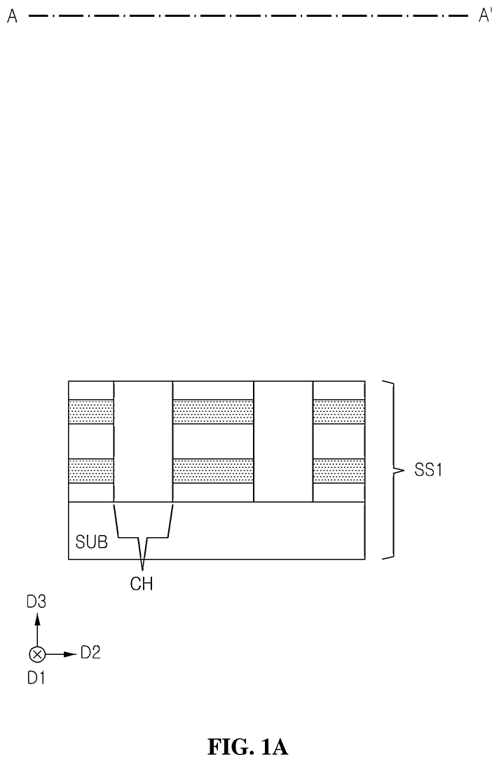

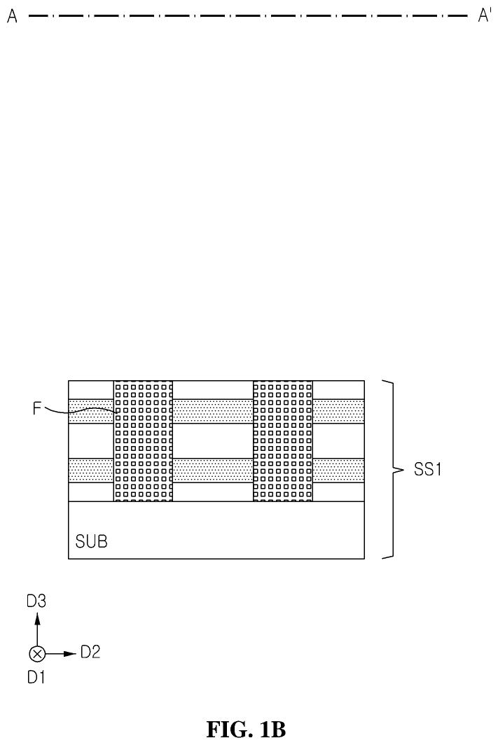

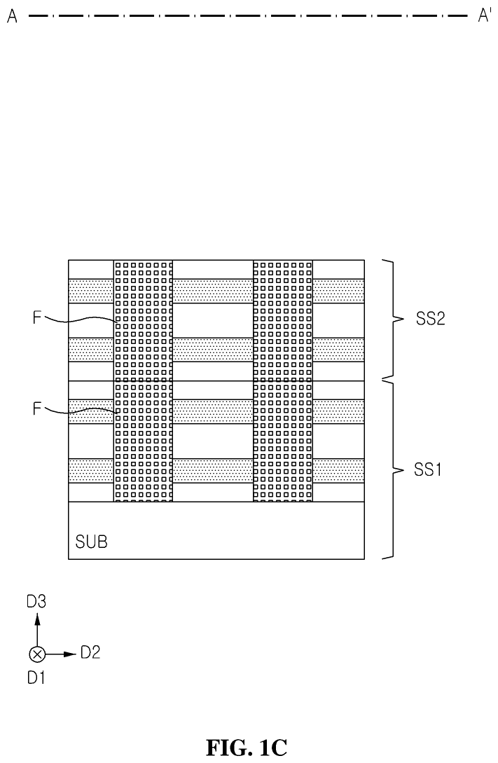

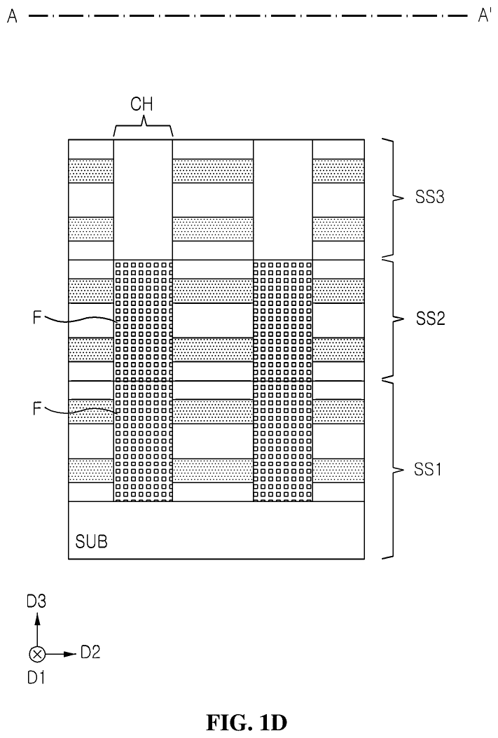

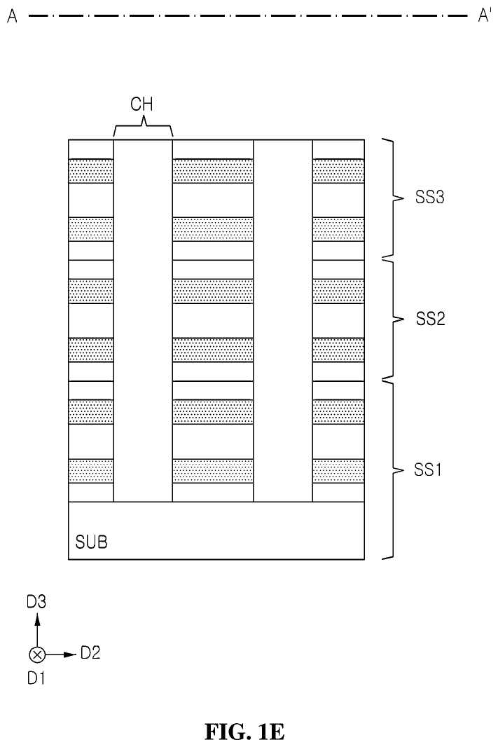

### BEST MODE

Hereinafter, embodiments of the present disclosure will be described in detail with reference to the accompanying drawing. However, the present disclosure is not restricted or limited by the embodiments. Further, the same reference numerals in each drawing indicate the same components.

Further, terms used in the specification are used to properly express the embodiments of the present disclosure, and the terms may change depending on the intention of a viewer or an operator or customs in the field to which the present disclosure belongs. Therefore, definitions of these terms should be made based on the content throughout the specification. For example, in the specification, a singular form also includes a plural form unless specifically mentioned in a phrase. Further, the term “comprise” and/or “comprising” used herein does not exclude the presence or addition of one or more other components, steps, operations, and/or elements in or to components, steps, operations, and/or elements mentioned above. Further, even though the terms such as first and second are used in the specification to describe various areas, directions, and shapes, the areas, directions, and shapes should not be limited by these terms. These terms are merely used to distinguish one area, direction or shape from another area, direction or shape. Thus, a portion/part referred to as a “first part/portion” in an embodiment may be referred to as a “second part/portion” in another embodiment.

Further, it should be understood that various embodiments of the present disclosure are different from each other but are not necessarily mutually exclusive. For example, specific shapes, specific structures, and specific characteristics described herein may be implemented in another embodiment without departing from the technical spirit and scope of the present disclosure in relation to the embodiment. Further, it should be understood that positions, arrangements, or configurations of individual components in the range of each presented embodiment may be changed without departing from the technical spirit and scope of the present disclosure.

Hereinafter, a three-dimensional flash memory and a method of manufacturing the same according to embodiments will be described in detail with reference to the accompanying drawings.

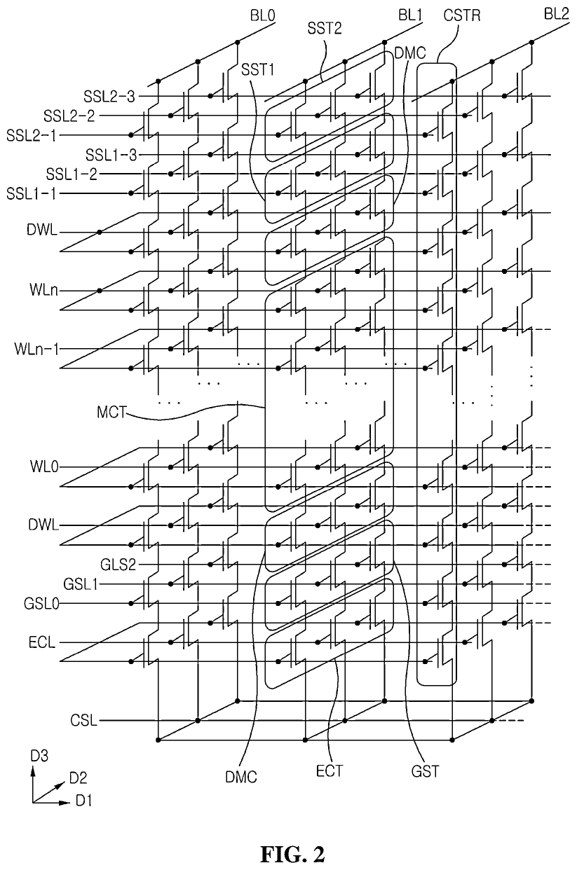

FIG. 2 is a schematic circuit diagram illustrating an array of the three-dimensional flash memory according to the embodiment.

Referring to FIG. 2, the array of the three-dimensional flash memory according to the embodiment may include a common source line CSL, a plurality of bit lines BL0, BL1, and BL2, and a plurality of cell strings CSTR arranged between the common source line CSL and the bit lines BL0, BL1, and BL2.

The bit lines BL0, BL1, and BL2 may be two-dimensionally arranged while being spaced apart from each other in a first direction D1 while extending in a second direction D2. Here, the first direction D1, the second direction D2, and a third direction D3 may be orthogonal to each other and may form a rectangular coordinate system defined by X, Y, and Z axes.

The plurality of cell strings CSTR may be connected in parallel to the bit lines BL0, BL1, and BL2, respectively. The cell strings CSTR may be commonly connected to the common source line CSL while being provided between the bit lines BL0, BL1, and BL2 and the one common source line CSL. In this case, a plurality of common source lines CSL may be provided, and the plurality of common source lines CSL may be two-dimensionally arranged while being spaced apart from each other in the second direction D2 while extending in the first direction D1. The same voltage may be electrically applied to the plurality of common source lines CSL, but the present disclosure is not restricted or limited thereto, and different voltages may be applied to the plurality of common source lines CSL as the plurality of common source lines CSL are electrically independently controlled.

The cell strings CSTR may be arranged spaced apart from each other in the second direction D2 for each bit line while extending in the third direction D3. According to an embodiment, each of the cell strings CSTR may include a ground selection transistor GST connected to the common source line CSL, first and second string selection transistors SST1 and SST2 connected to the bit lines BL0, BL1, and BL2 and connected in series to each other, memory cell transistors MCT arranged between the ground selection transistor GST and the first and second string selection transistors SST1 and SST2 and connected in series to each other, and an erasure control transistor ECT. Further, each of the memory cell transistors MCT may include a data storage element.

As an example, each of the cell strings CSTR may include the first and second string selection transistors SST1 and SST2 connected in series to each other, and the second string selection transistor SST2 may be connected to one of the bit lines BL0, BL1, and BL2. However, the present disclosure is not restricted or limited thereto, and each of the cell strings CSTR may include one string selection transistor. As another example, the ground selection transistor GST in each of the cell strings CSTR may include a plurality of metal oxide semiconductor (MOS) transistors connected in series to each other, which is similar to the first and second string selection transistors SST1 and SST2.

The one cell string CSTR may include the plurality of memory cell transistors MCT having different distances from the common source lines CSL. That is, the memory cell transistors MCT may be connected in series to each other while being arranged between the first string selection transistor SST1 and the ground selection transistor GST in the third direction D3. The erasure control transistor ECT may be connected between the ground selection transistor GST and the common source lines CSL. Each of the cell strings CSTR may further include dummy cell transistors DMC connected between the first string selection transistor SST1 and an uppermost one of the memory cell transistors MCT and between the ground selection transistor GST and a lowermost one of the memory cell transistors MCT.

According to the embodiment, the first string selection transistor SST1 may be controlled by first string selection lines SSL1-1, SSL1-2, and SSL1-3, and the second string selection transistor SST2 may be controlled by second string selection lines SSL2-1, SSL2-2, and SSL2-3. The memory cell transistors MCT may be controlled by a plurality of word lines WL0 to WLn, and the dummy cell transistors DMC may be controlled by a dummy word line DWL. The ground selection transistor GST may be controlled by ground selection lines GSL0, GSL1, and GSL2, and the erasure control transistor ECT may be controlled by an erasure control line ECL. A plurality of erasure control transistors ECT may be provided. The common source lines CSL may be commonly connected to sources of the erasure control transistors ECT.

Gate electrodes of the memory cell transistors MCT, which are provided at substantially the same distance from the common source lines CSL, may be commonly connected to one of the word lines WL0 to WLn and DWL and thus may be in an equipotential state. However, the present disclosure is not restricted or limited thereto, and even when the gate electrodes of the memory cell transistors MCT are provided at substantially the same level from the common source lines CSL, the gate electrodes provided in different rows or columns may be independently controlled.

The ground selection lines GSL0, GSL1, and GSL2, the first string selection lines SSL1-1, SSL1-2, and SSL1-3, and the second string selection lines SSL2-1, SSL2-2, and SSL2-3 may be two-dimensionally arranged while extending in the first direction D1 and being spaced apart from each other in the second direction D2. The ground selection lines GSL0, GSL1, and GSL2, the first string selection lines SSL1-1, SSL1-2, and SSL1-3, and the second string selection lines SSL2-1, SSL2-2, and SSL2-3, which are provided at substantially the same level from the common source lines CSL, may be electrically separated from each other. Further, the erasure control transistors ECT of different cell strings CSTR may be controlled by the common erasure control line ECL. The erasure control transistors ECT may generate gate induced drain leakage (hereinafter, referred to as GIDL) during an operation of erasing a memory cell array. In some embodiments, during the operation of erasing the memory cell array, an erasure voltage may be applied to the bit lines BL0, BL1, and BL2 and/or the common source lines CSL, and a gate induced leakage current may be generated in the string selection transistor SST and/or the erasure control transistors ECT.

The string selection line SSL may be expressed as an upper selection line USL, and the ground selection line GSL may be expressed as a lower selection line.

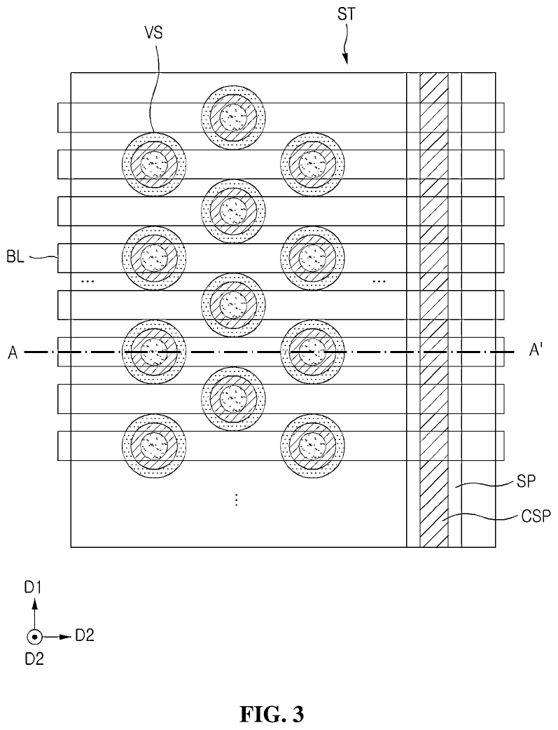

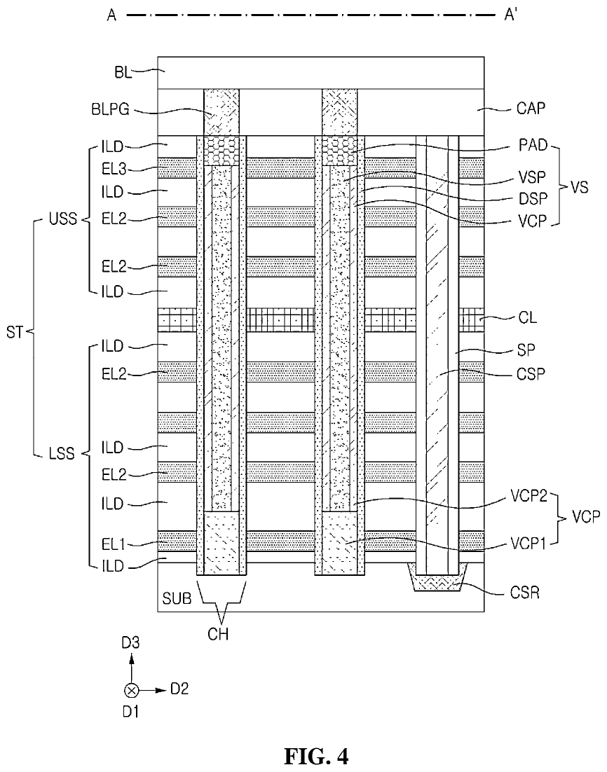

FIG. 3 is a plan view illustrating the structure of the three-dimensional flash memory according to the embodiment, and FIG. 4 is a cross-sectional view illustrating the structure of the three-dimensional flash memory illustrated in FIG. 3 and corresponds to a cross section along line A-A′ of FIG. 3.

Referring to FIGS. 3 and 4, a substrate SUB may be a semiconductor substrate such as a silicon substrate, a silicon-germanium substrate, a germanium substrate, or a monocrystalline epitaxial layer grown on a monocrystalline silicon substrate. The substrate SUB may be doped with first conductivity-type impurities (e.g., P-type impurities).

Stack structures ST may be arranged on the substrate SUB. The stack structures ST may be two-dimensionally arranged in the second direction D2 while extending in the first direction D1. Further, the stack structures ST may be spaced apart from each other in the second direction D2.

Each of the stack structures ST may include gate electrodes EL1, EL2, and EL3 and interlayer insulating films ILD alternately stacked in a vertical direction perpendicular to an upper surface of the substrate SUB (e.g., in the third direction D3). The stack structures ST may have substantially flat upper surfaces. That is, the upper surfaces of the stack structures ST may be parallel to the upper surface of the substrate SUB. Hereinafter, the vertical direction means the third direction D3 or a direction opposite to the third direction D3.

Referring back to FIG. 2, each of the gate electrodes EL1, EL2, and EL3 may be one of the erasure control line ECL, the ground selection lines GSL0, GSL1, and GSL2, the word lines WL0 to WLn and DWL, the first string selection lines SSL1-1, SSL1-2, and SSL1-3, and the second string selection lines SSL2-1, SSL2-2, and SSL2-3 that are sequentially stacked on the substrate SUB.

Each of the gate electrodes EL1, EL2, and EL3 may have substantially the same thickness in the third direction D3 while extending in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like), or the like. Each of the gate electrodes EL1, EL2, and EL3 may include at least one of all metal materials that may be formed by ALD in addition to the metal material described above.

In more detail, the gate electrodes EL1, EL2, and EL3 may include the lowermost first gate electrode EL1, the uppermost third gate electrode EL3, and the plurality of second gate electrodes EL2 between the first gate electrode EL1 and the third gate electrode EL3. Although each of the first gate electrode EL1 and the third gate electrode EL3 is illustrated and described in a singular number, this is illustrative, and the present disclosure is not limited thereto. As needed, the plurality of first gate electrodes EL1 and the plurality of third gate electrodes EL3 may also be provided. The first gate electrode EL1 may correspond to one of the ground selection lines GSL0, GSL1, and GSL2 illustrated in FIG. 2. The second gate electrode EL2 may correspond to any one of the word lines WL0 to WLn and DWL illustrated in FIG. 2. The third gate electrode EL3 may correspond to any one of the first string selection lines SSL1-1, SSL1-2, and SSL1-3 or any one of the second string selection lines SSL2-1, SSL2-2, and SSL2-3 illustrated in FIG. 2.

Although not illustrated, an end of each of the stack structures ST may have a stepwise structure in the first direction D1. In more detail, the lengths of the gate electrodes EL1, EL2, and EL3 of the stack structures ST in the first direction D1 may decrease as distances from the substrate SUB increase. The third gate electrode EL3 may have the smallest length in the first direction D1 and the largest distance spaced apart from the substrate SUB in the third direction D3. The first gate electrode EL1 may have the largest length in the first direction D1 and the smallest distance spaced apart from the substrate SUB in the third direction D3. Due to the stepwise structure, the thickness of each of the stack structures ST may decrease as a distance from the outermost one of vertical channel structures VS, which will be described below, increases, and side walls of the gate electrodes EL1, EL2, and EL3 may be spaced apart from each other at regular intervals in the first direction D1 when viewed from a plane.

The interlayer insulating films ILD may have different thicknesses. As an example, the lowermost one and the uppermost one of the interlayer insulating films ILD may have a thickness that is smaller than those of the other interlayer insulating films ILD. However, this is illustrative, and the present disclosure is not limited thereto. The interlayer insulating films ILD may be set to have different thickness or the same thickness according to characteristics of a semiconductor device. The interlayer insulating films ILD may be formed of an insulating material to insulate the gate electrodes EL1, EL2, and EL3 from each other. As an example, the interlayer insulating films ILD may be formed of a silicon oxide.

A plurality of channel holes CH passing through portions of the stack structures ST and the substrate SUB may be provided. The vertical channel structures VS may be provided inside the channel holes CH. The vertical channel structures VS, which are the plurality of cell strings CSTR illustrated in FIG. 2, may extend in the third direction D3 while being connected to the substrate SUB. The connection of the vertical channel structures VS with the substrate SUB may be achieved as a lower surface of a portion of each of the vertical channel structures VS is in contact with the upper surface of the substrate SUB, but the present disclosure is not restricted or limited thereto, and the connection of the vertical channel structures VS with the substrate SUB may be achieved as the vertical channel structures VS are buried in the substrate SUB. When the portion of each of the vertical channel structures VS is buried in the substrate SUB, lower surfaces of the vertical channel structures VS may be positioned at a lower level than that of the upper surface of the substrate SUB.

A plurality of columns of the vertical channel structures VS passing through any one of the stack structures ST may be provided. For example, as illustrated in FIG. 2, three columns of the vertical channel structures VS may pass through one of the stack structures ST. However, the present disclosure is not restricted or limited thereto, and the two columns of the vertical channel structures VS may pass through one of the stack structures ST or four or more columns of the vertical channel structures VS may pass through one of the stack structures ST. In the pair of adjacent columns, the vertical channel structures VS corresponding to one column may be shifted in the first direction D1 from the vertical channel structures VS corresponding to the other one column adjacent thereto. When viewed from a plane, the vertical channel structures VS may be arranged in a zigzag shape in the first direction D1. However, the present disclosure is not restricted or limited thereto, and the vertical channel structures VS may form an array in which the vertical channel structures VS are arranged side by side in rows and columns.

Each of the vertical channel structures VS may be formed to extend from the substrate SUB in the third direction D3. It is illustrated in the drawings that each of the vertical channel structures VS has a column shape having the same width at an upper end and a lower end thereof, but the present disclosure is not restricted or limited thereto, and each of the vertical channel structures VS may have a shape of which widths in the first direction D1 and the second direction D2 increase toward the third direction D3. The upper surface of each of the vertical channel structures VS may have a circular shape, an elliptical shape, a quadrangular shape, or a bar shape.

Each of the vertical channel structures VS may include a data storage pattern DSP, a vertical channel pattern VCP, a vertical semiconductor pattern VSP, and a conductive pad PAD. In each of the vertical channel structures VS, the data storage pattern DSP may have a pipe shape or a macaroni shape with an opened lower end, and the vertical channel pattern VCP may have a pipe shape or a macaroni shape with a closed lower end. The vertical semiconductor pattern VSP may fill a space surrounded by the vertical channel pattern VCP and the conductive pad PAD.

While covering inner walls of the channel holes CH, the data storage pattern DSP may inwardly surround the outer wall of the vertical channel pattern VCP and may be outwardly in contact with the side walls of the gate electrodes EL1, EL2, and EL3. Accordingly, areas of the data storage pattern DSP, which correspond to the second gate electrodes EL2, together with areas of the vertical channel pattern VCP, which correspond to the second gate electrodes EL2, may constitute memory cells in which a memory operation (e.g., a program operation, a reading operation, or an erasure operation) is performed by voltages applied through the second gate electrodes EL2. The memory cells correspond to the memory cell transistors MCT illustrated in FIG. 2. That is, the data storage pattern DSP may trap charges or holes by the voltages applied through the second gate electrodes EL2 or may maintain states of the charges (e.g., polarization states of the charges) by the voltages applied through the second gate electrodes EL2, and thus, the data storage pattern DSP may serve as data storage in the three-dimensional flash memory. For example, a tunneling oxide film (oxide)-charge storage film (nitride)-blocking oxide (oxide) (ONO) layer or a ferroelectric layer may be used as the data storage pattern DSP. The data storage pattern DSP may indicate a binary data value or a multi-value data value through a change in the amount of trapped charges or holes or may indicate the binary data value or the multi-value data value through state change of the charges.

The vertical channel pattern VCP may cover an inner wall of the data storage pattern DSP. The vertical channel pattern VCP may include a first part VCP1 and a second part VCP2 on the first part VCP1.

The first part VCP1 of the vertical channel pattern VCP may be provided under each of the channel holes CH and may be in contact with the substrate SUB. The first part VCP1 of the vertical channel pattern VCP may be used to block, suppress, or minimize a leakage current in each of the vertical channel structures VS and/or used as an epitaxial pattern. A thickness of the first part VCP1 of the vertical channel pattern VCP may be greater than, for example, the thickness of the first gate electrode EL1. A side wall of the first part VCP1 of the vertical channel pattern VCP may be surrounded by the data storage pattern DSP. An upper surface of the first part VCP1 of the vertical channel pattern VCP may be positioned at a higher level than that of an upper surface of the first gate electrode EL1. In more detail, the upper surface of the first part VCP1 of the vertical channel pattern VCP may be positioned between the upper surface of the first gate electrode EL1 and a lower surface of the lowermost one of the second gate electrodes EL2. A lower surface of the first part VCP1 of the vertical channel pattern VCP may be positioned at a lower level than an uppermost surface of the substrate SUB (i.e., the lower surface of the lowermost one of the interlayer insulating films ILD). A portion of the first part VCP1 of the vertical channel pattern VCP may overlap the first gate electrode EL1 in a horizontal direction. Hereinafter, the horizontal direction refers to a predetermined direction extending on a plane parallel to the first direction D1 and the second direction D2.

The second part VCP2 of the vertical channel pattern VCP may extend from the upper surface of the first part VCP1 in the third direction D3. The second part VCP2 of the vertical channel pattern VCP may be provided between the data storage pattern DSP and the vertical semiconductor pattern VSP and may correspond to the second gate electrodes EL2. Accordingly, as described above, the second part VCP2 of the vertical channel pattern VCP may constitute the memory cells together with the areas of the data storage pattern DSP, which correspond to the second gate electrodes EL2.

An upper surface of the second part VCP2 of the vertical channel pattern VCP may be substantially coplanar with an upper surface of the vertical semiconductor pattern VSP. The upper surface of the second part VCP2 of the vertical channel pattern VCP may be positioned at a level higher than an upper surface of the uppermost one of the second gate electrodes EL2. In more detail, the upper surface of the second part VCP2 of the vertical channel pattern VCP may be positioned between an upper surface and a lower surface of the third gate electrode EL3.

The vertical channel pattern VCP, which is a component for transferring charges or holes to the data storage pattern DSP, may be formed of monocrystalline silicon or polysilicon such that a channel is formed or boosted by a voltage applied thereto. However, the present disclosure is not restricted or limited thereto. For example, the vertical channel pattern VCP may be formed of an oxide semiconductor material capable of blocking, suppressing, or minimizing a leakage current. For example, the vertical channel pattern VCP may be formed of an oxide semiconductor material including at least one of In, Zn, and Ga having excellent leakage current characteristics or a group 4 semiconductor material. The vertical channel pattern VCP may be formed of, for example, a ZnOₓ-based material including AZO, ZTO, IZO, ITO, IGZO, or Ag—ZnO. Thus, the vertical channel pattern VCP may block, suppress, or minimize a leakage current to the gate electrodes EL1, EL2, and EL3 or the substrate SUB, may improve transistor characteristics (e.g., a threshold voltage distribution and a program/read operation speed) of at least one of the gate electrodes EL1, EL2, and EL3, and as a result, may improve electrical characteristics of the three-dimensional flash memory.

The vertical semiconductor pattern VSP may be surrounded by the second part VCP2 of the vertical channel pattern VCP. The upper surface of the vertical semiconductor pattern VSP may be in contact with the conductive pad PAD, and a lower surface of the vertical semiconductor pattern VSP may be in contact with the first part VCP1 of the vertical channel pattern VCP. The vertical semiconductor pattern VSP may be spaced apart from the substrate SUB in the third direction D3. In other words, the vertical semiconductor pattern VSP may be electrically floating from the substrate SUB.

The vertical semiconductor pattern VSP may be formed of a material that helps diffusion of charges or holes in the vertical channel pattern VCP. In more detail, the vertical semiconductor pattern VSP may be formed of a material having excellent charge and hole mobility. For example, the vertical semiconductor pattern VSP may be formed of a semiconductor material doped with impurities, an intrinsic semiconductor material not doped with impurities, or a polycrystalline semiconductor material. For a more detailed example, the vertical semiconductor pattern VSP may be formed of a polysilicon doped with first conductivity-type impurities (e.g., P-type impurities), which is like the substrate SUB. That is, the vertical semiconductor pattern VSP may improve the electrical characteristics of the three-dimensional flash memory to increase a memory operation speed.

Referring back to FIG. 2, the vertical channel structures VS may correspond to channels of the erasure control transistor ECT, the first and second string selection transistors SST1 and SST2, the ground selection transistor GST, and the memory cell transistors MCT.

The conductive pad PAD may be provided on the upper surface of the second part VCP2 of the vertical channel pattern VCP and on the upper surface of the vertical semiconductor pattern VSP. The conductive pad PAD may be connected to an upper portion of the vertical channel pattern VCP and an upper portion of the vertical semiconductor pattern VSP. A side wall of the conductive pad PAD may be surrounded by the data storage pattern DSP. An upper surface of the conductive pad PAD may be substantially coplanar with an upper surface of each of the stack structures ST (i.e., an upper surface of the uppermost one of the interlayer insulating films ILD). A lower surface of the conductive pad PAD may be positioned at a lower level than that of the upper surface of the third gate electrode EL3. In more detail, the lower surface of the conductive pad PAD may be positioned between the upper surface and the lower surface of the third gate electrode EL3. That is, at least a portion of the conductive pad PAD may overlap the third gate electrode EL3 in the horizontal direction.

The conductive pad PAD may be formed of a semiconductor doped with impurities or a conductive material. For example, the conductive pad PAD may be formed of a semiconductor material doped with impurities different from those of the vertical semiconductor pattern VSP (in more detail, second conductivity-type (e.g., N-type) impurities different from the first conductivity-type (e.g., P-type) impurities).

The conductive pad PAD may reduce contact resistance between a bit line BL, which will be described below, and the vertical channel pattern VCP (or the vertical semiconductor pattern VSP).

Hereinafter, it has been described that the vertical channel structures VS have a structure including the conductive pad PAD, but the present disclosure is not restricted or limited thereto, and the vertical channel structures VS may have a structure in which the conductive pad PAD is omitted. In this case, as the conductive pad PAD is omitted from the vertical channel structures VS, each of the vertical channel pattern VCP and the vertical semiconductor pattern VSP may extend in the third direction D3 so that the upper surface of each of the vertical channel pattern VCP and the vertical semiconductor pattern VSP is substantially coplanar with the upper surface of each of the stack structures ST (i.e., the upper surface of the uppermost one of the interlayer insulating films ILD). Further, in this case, a bit line contact plug BLPG, which will be described below, may be in direct contact with and electrically connected to the vertical channel pattern VCP instead of being indirectly electrically connected to the vertical channel pattern VCP through the conductive pad PAD.

Further, it has been described that the vertical channel structures VS include the vertical semiconductor pattern VSP, but the present disclosure is not restricted or limited thereto, and the vertical semiconductor pattern VSP may be omitted.

Further, it has been described that the vertical channel pattern VCP has a structure including the first part VCP1 and the second part VCP2, but the present disclosure is not restricted or limited thereto, and the vertical channel pattern VCP may have a structure in which the first part VCP1 is excluded. For example, the vertical channel pattern VCP may be provided between the vertical semiconductor pattern VSP that is formed to extend to the substrate SUB and the data storage pattern DSP and may be formed to extend to the substrate SUB to be in contact with the substrate SUB. In this case, a lower surface of the vertical channel pattern VCP may be positioned at a lower level than that of the uppermost surface of the substrate SUB (the lower surface of the lowermost one of the interlayer insulating films ILD), and the upper surface of the vertical channel pattern VCP may be substantially coplanar with the upper surface of the vertical semiconductor pattern VSP.

Although not illustrated in the drawings, a separation trench TR extending in the first direction D1 may be provided between the adjacent stack structures ST. The separation trench TR may separate and isolate each of the stack structures ST to form a single block.

A common source area CSR may be provided inside the substrate SUB exposed by the separation trench TR. The common source area CSR may extend in the first direction D1 within the substrate SUB. The common source area CSR may be formed of a semiconductor material doped with the second conductive-type impurities (e.g., the N-type impurities). The common source area CSR may correspond to the common source line CSL of FIG. 2.

A common source plug CSP may be provided inside the separation trench TR. The common source plug CSP may be connected to the common source area CSR. An upper surface of the common source plug CSP may be substantially coplanar with the upper surface of each of the stack structures ST (i.e., the upper surface of the uppermost one of the interlayer insulating films ILD). The common source plug CSP may have a plate shape extending in the first direction D1 and the third direction D3. In this case, the common source plug CSP may have a shape of which a width in the second direction D2 increases toward the third direction D3.

Insulation spacers SP may be interposed between the common source plug CSP and the stack structures ST. The insulation spacers SP may be provided between the adjacent stack structures ST to face each other. For example, the insulation spacers SP may be formed of a silicon oxide, a silicon nitride, a silicon oxy nitride, or a low-k material having a low dielectric constant.

A capping insulating film CAP may be provided on the stack structures ST, the vertical channel structures VS, and the common source plug CSP. The capping insulating film CAP may cover the upper surface of the uppermost one of the interlayer insulating films ILD, the upper surface of the conductive pad PAD, and the upper surface of the common source plug CSP. The capping insulating film CAP may be formed of an insulating material different from that of the interlayer insulating films ILD. The bit line contact plug BLPG electrically connected to the conductive pad PAD may be provided inside the capping insulating film CAP. The bit line contact plug BLPG may have a shape of which widths in the first direction D1 and the second direction D2 increase toward the third direction D3.

The bit line BL may be provided on the capping insulating film CAP and the bit line contact plug BLPG. The bit line BL may correspond to any one of the plurality of bit lines BL0, BL1, and BL2 illustrated in FIG. 2 and may be formed of a conductive material to extend in the second direction D2. The conductive material constituting the bit line BL may be the same material as the conductive material forming each of the gate electrodes EL1, EL2, and EL3.

The bit line BL may be electrically connected to the vertical channel structures VS through the bit line contact plug BLPG. Here, the fact that the bit line BL is connected to the vertical channel structures VS may mean that the bit line BL is connected to the vertical channel pattern VCP included in the vertical channel structures VS.

The three-dimensional flash memory having such a structure may perform the program operation, the read operation, and the erasure operation based on a voltage applied to each of the cell strings CSTR, a voltage applied to the string selection line SSL, a voltage applied to each of the word lines WL0 to WLn, a voltage applied to the ground selection line GSL, and a voltage applied to the common source line CSL. For example, the three-dimensional flash memory may perform the program operation by forming a channel in the vertical channel pattern VCP and transferring charges or holes to the data storage pattern DSP of the target memory cell, based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Further, the three-dimensional flash memory according to the embodiment is not restricted or limited to the above structure, and according to an implementation example, the three-dimensional flash memory may be implemented in various structures under a condition that the vertical channel pattern VCP, the data storage pattern DSP, the gate electrodes EL1, EL2, and EL3, the bit line BL, and the common source line CSL are included.

For example, the three-dimensional flash memory may be implemented in a structure including a back gate BG instead of the vertical semiconductor pattern VSP in contact with an inner wall of the vertical channel pattern VCP. In this case, while at least a portion of the back gate BG is surrounded by the vertical channel pattern VCP to apply the voltage for the memory operation to the vertical channel pattern VCP, the back gate BG may be formed of a conductive material including at least one selected from a doped semiconductor (e.g., a doped silicon or the like), a metal (e.g., W (tungsten), Cu (copper), Al (aluminum), Ti (titanium), Ta (tantalum), Mo (molybdenum), Ru (ruthenium), Au (gold), or the like), a conductive metal nitride (e.g., a titanium nitride, a tantalum nitride, or the like) or the like in the vertical direction (e.g., the third direction D3).

As the three-dimensional flash memory having such a structure is manufactured through a stack laminating process, each of the stack structures ST may include an upper stack structure USS and a lower stack structure LSS. The lower stack structure LSS may be disposed on the substrate SUB and include the gate electrodes (EL1 and a portion of EL2) and the interlayer insulating films ILD that are vertically and alternately stacked. The upper stack structure USS may be stacked on the lower stack structure LSS and include the gate electrodes (a portion of EL2 and EL3) and the interlayer insulating films ILD that are vertically and alternately stacked.

When the lower stack structure LSS and the upper stack structure USS are stacked, an etching profile of the vertical channel structures VS included in the lower stack structure LSS and an etching profile of the vertical channel structures VS included in the upper stack structure USS may not be maintained uniformly, and thus the vertical channel structures VS included in the lower stack structure LSS and the vertical channel structures VS included in the upper stack structure USS may not be connected to each other. This may cause degradation of reliability and performance of a memory. For example, when the vertical channel pattern VCP of the lower stack structure LSS and the vertical channel pattern VCP of the upper stack structure USS may not be connected to each other, channel current characteristics may be degraded.

Accordingly, each of the stack structures ST of the three-dimensional flash memory according to one embodiment may include a capping layer CL that connects the vertical channel structures VS of the stack structures USS and LSS to each other so that the etching profiles of the vertical channel structures VS of the stack structures USS and LSS are uniformly maintained while being disposed between the stack structures USS and LSS.

The capping layer CL may connect the channel holes CH to each other as a capping film (not illustrated) having a size that is smaller than a size of each of the channel holes CH of the stack structures USS and LSS on a plane is removed in a process of etching the channel holes CH and thus may connect the vertical channel structures VS to each other while uniformly maintaining the etching profiles of the vertical channel structures VS.

As described, the three-dimensional flash memory may include the capping layer CL to connect the vertical channel structures VS while uniformly maintaining the etching profiles of the vertical channel structures VS of the stack structures USS and LSS, thereby solving problems of degraded reliability and performance of the memory.

Hereinabove, it has been described that the three-dimensional flash memory may include two stack structures such as the upper stack structure USS and the lower stack structure LSS. However, the number of stack structures stacked in a stack laminating process may be adjusted and thus the three-dimensional flash memory may include three or more stack structures (e.g., the upper stack structures USS, middle stack structures MSS, and the lower stack structures LSS). The capping layer CL for connecting the vertical channel structures VS of the stack structures may be disposed between the stack structures, three or more stack structures are stacked, and thus the capping layer CL may also be provided as a plurality of capping layers CL. The plurality of capping layers CL may be spaced apart from each other in the third direction D3 and arranged at connection portions of the stack structures.

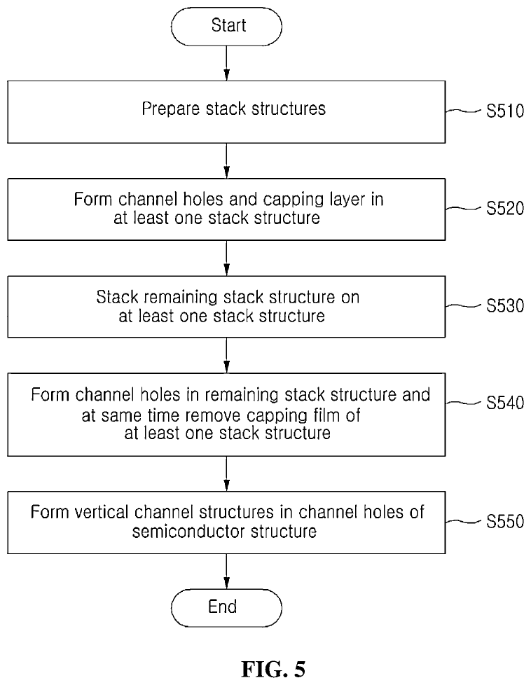

FIG. 5 is a flowchart illustrating the method of manufacturing the three-dimensional flash memory according to the embodiment in which a gate first method is applied to manufacture the three-dimensional flash memory illustrated in FIGS. 2 to 3, and FIGS. 6A to 6J are cross-sectional views illustrating the structure of the three-dimensional flash memory to describe the method of manufacturing the three-dimensional flash memory illustrated in FIG. 5.

Hereinafter, the method of manufacturing the three-dimensional flash memory according to the embodiment is intended to manufacture the three-dimensional flash memory having the structure described with reference to FIGS. 2 to 4 by applying the gate first method, and it is assumed that the method is performed by an automated and mechanized manufacturing system.

Further, hereinafter, for convenience of description, the manufacturing method is described as manufacturing the three-dimensional flash memory having a structure including the interlayer insulating films ILD, the word lines WL0 to WLn, the vertical channel structures VS, and the capping layer CL. Because the materials constituting the components of the three-dimensional flash memory have been described with reference to FIGS. 2 to 4, a detailed description thereof will be omitted.

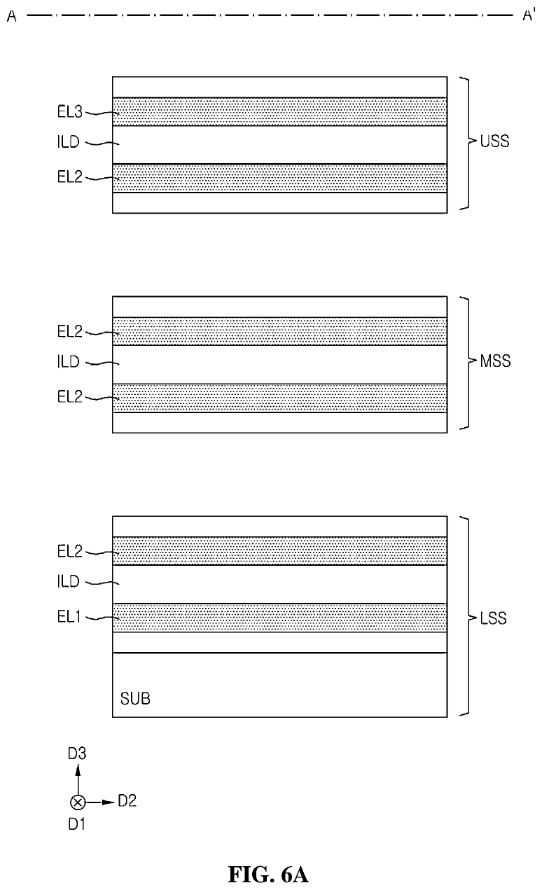

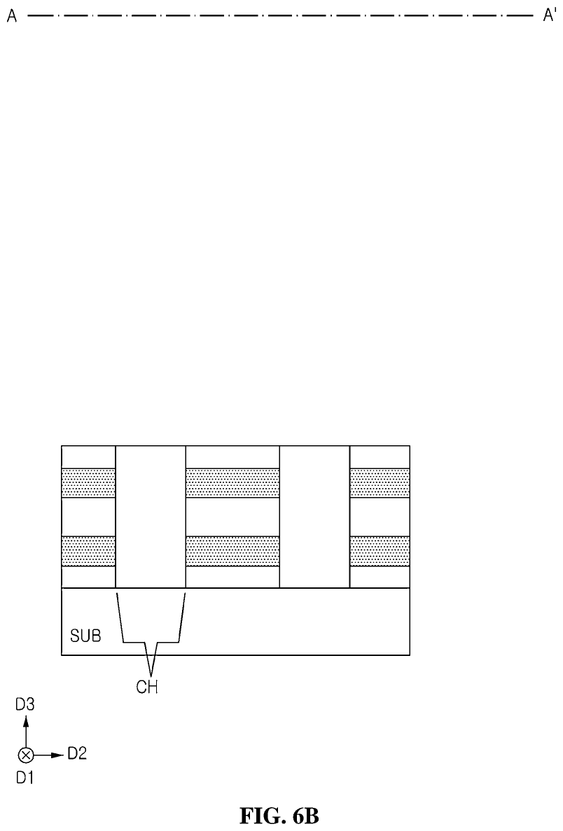

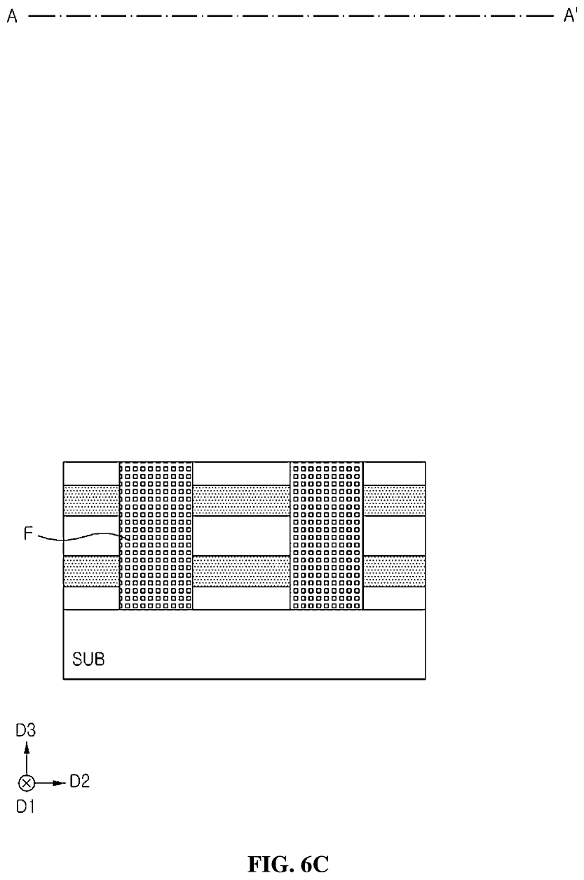

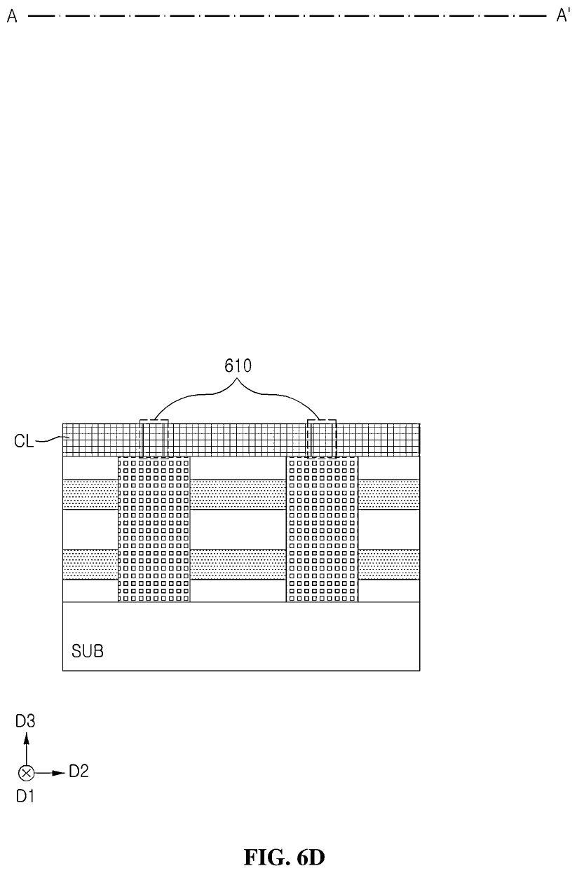

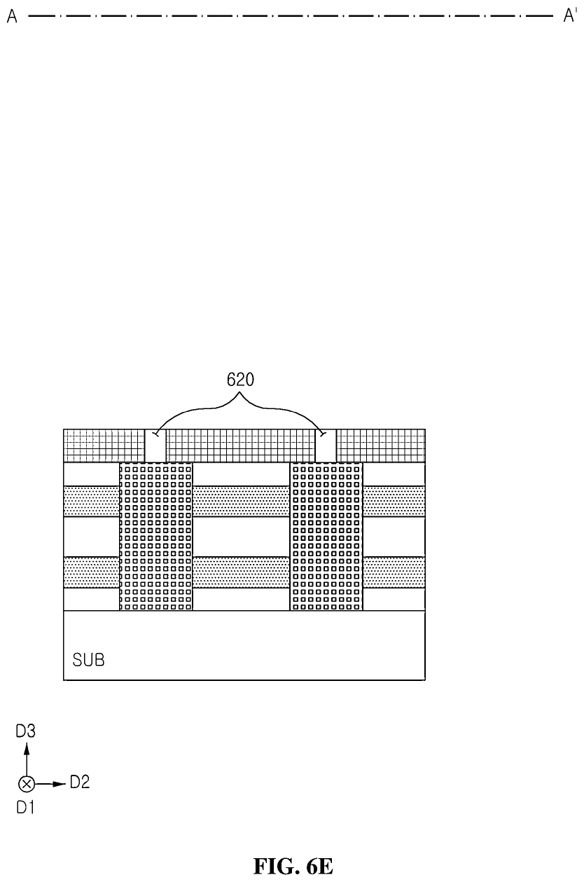

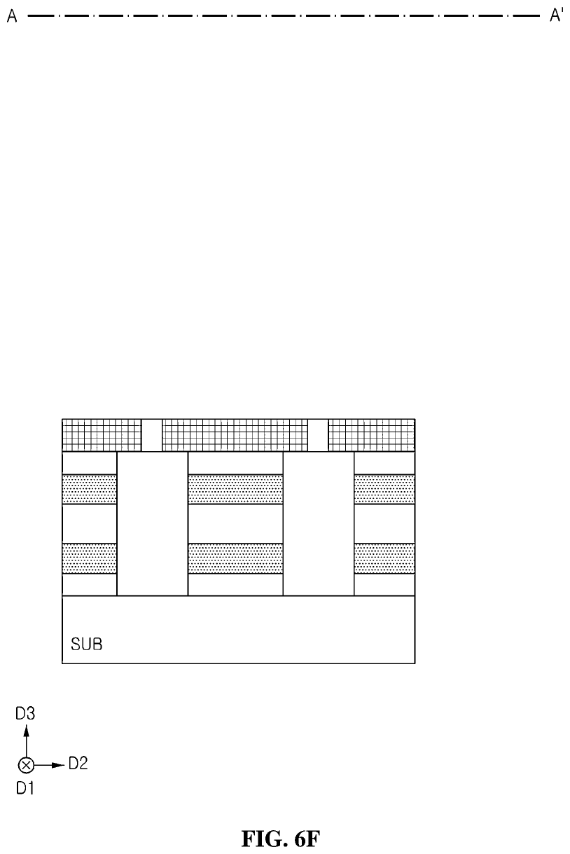

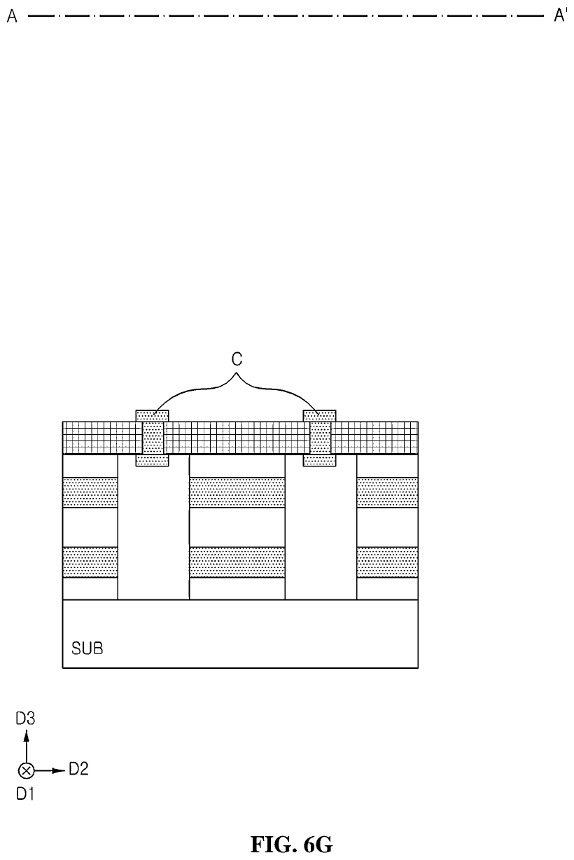

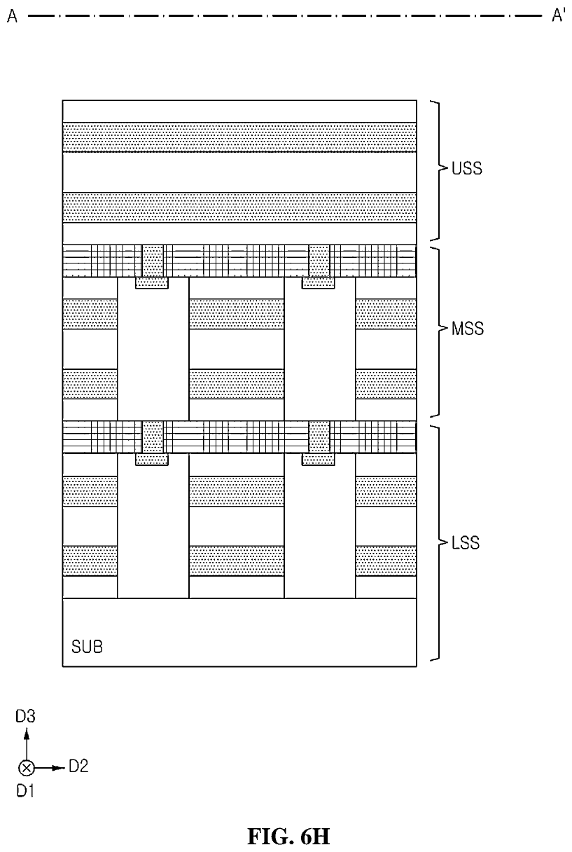

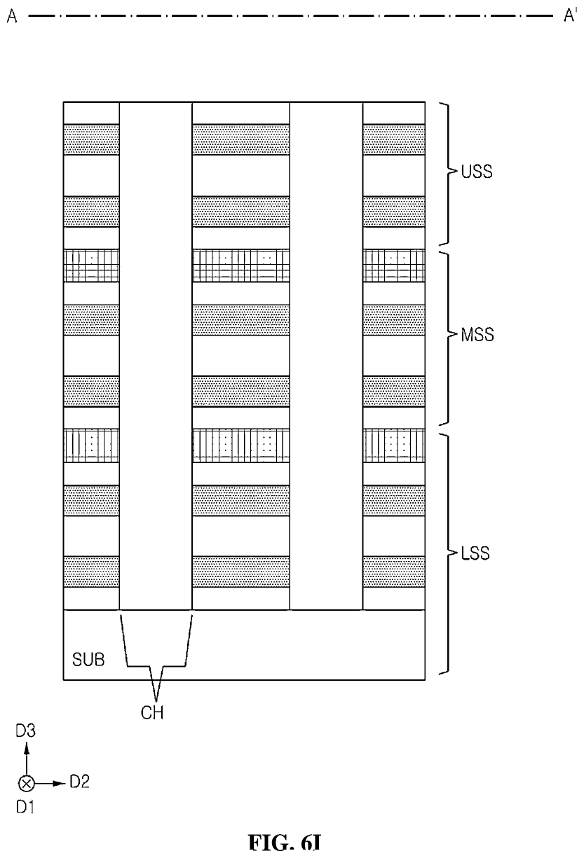

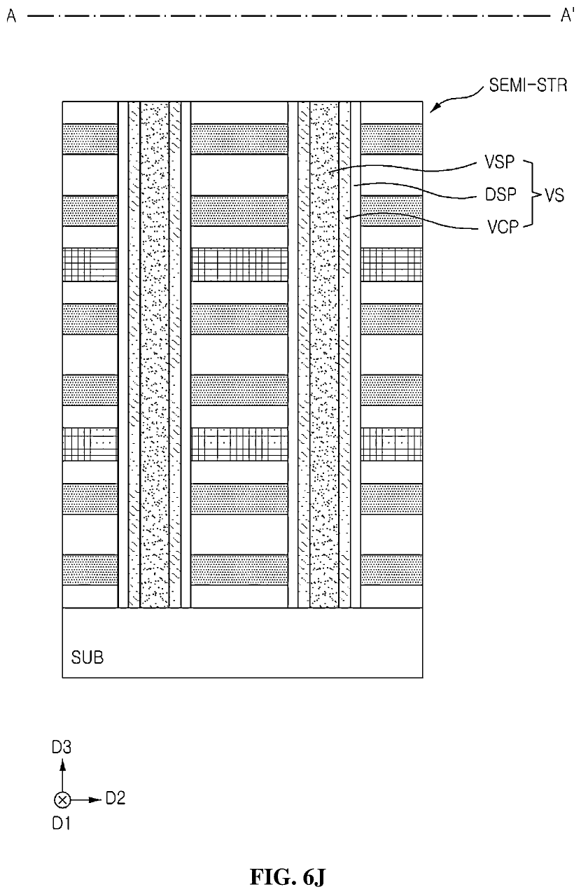

Referring to FIG. 5, in operation S510, as illustrated in FIG. 6A, the manufacturing system may prepare the stack structures USS, MSS, and LSS including the interlayer insulating films ILD and the gate electrodes EL1 to EL3 formed to extend in the horizontal direction and alternately stacked in the vertical direction (e.g., the third direction D3).

In operation S520, as illustrated in FIGS. 6B to 6G, the manufacturing system may form the capping layer CL including the channel holes CH and a capping film “C” in at least one stack structure LSS among the stack structures USS, MSS, and LSS.

In more detail, the manufacturing system may form the channel holes CH in the at least one stack structure LSS as illustrated in FIG. 6B, form a filling film “F” in the channel holes CH as illustrated in FIG. 6C, form the capping layer CL on the at least one stack structure LSS on which the filling film “F” is formed as illustrated in FIG. 6D, etch a partial area 610 of the capping layer CL as illustrated in FIG. 6E, remove the filling film “F” through a space 620 in which the partial area 610 of the capping layer CL is etched as illustrated in FIG. 6F, and thus form the capping film “C” in the space 620 in which the partial area 610 of the capping layer CL is etched as illustrated in FIG. 6G.

In this case, because the etched partial area 610 of the capping layer CL has a size that is smaller than a size of each of the channel holes CH included in the at least one stack structure LSS on a plane, the capping film “C” formed in the space 620 in which the partial area 610 of the capping layer CL is etched may also have a size that is smaller than the size of each of the channel holes CH included in the at least one stack structure LSS on a plane. That is, as illustrated in FIG. 6G, the forming of the capping film “C” in the space 620 in which the partial area 610 of the capping layer CL is etched may mean forming of the capping film “C” having the size that is smaller than the size of each of the channel holes CH included in the at least one stack structure LSS on a plane.

In this way, the capping film “C” may be formed on the capping layer CL to have the size that is smaller than the size of each of the channel holes CH included in the at least one stack structure LSS on a plane, thus may be removed in a process of etching the channel holes CH in the remaining stack structure USS, and may connect the channel holes CH of the remaining stack structure USS to the channel holes CH of the at least one stack structure LSS.

Here, a process of etching the partial area 610 of the capping layer CL may be performed so that a profile of the space 620 in which the partial area 610 of the capping layer CL is etched is various. For example, as illustrated in FIG. 6E, the manufacturing system may perform an etching process on the partial area 610 of the capping layer CL such that the space 620 in which the partial area 610 of the capping layer CL is etched has a uniform profile in the vertical direction. As another example, the manufacturing system may perform an etching process on the partial area 610 of the capping layer CL such that the space 620 in which the partial area 610 of the capping layer CL is etched has a negative profile or a positive profile in the vertical direction.

Further, as illustrated in FIG. 6C, the filling film “F” formed in the channel holes CH may be formed of a material that may be removed through the space 620 from which the partial area 610 of the capping layer CL having the size that is smaller than the size of each of the channel holes CH included in the at least one stack structure LSS on a plane is removed.

Further, the manufacturing system may perform operation S520 for at least one stack structure MSS.

Hereinafter, since a case in which the manufacturing system manufactures the three-dimensional flash memory by stacking the three stack structures LSS, MSS, and USS has been described, operation S520 is performed on the two stack structures LSS and MSS. However, when the three-dimensional flash memory is manufactured by stacking four or more stack structures, operation S520 may be performed on all the remaining stack structures except for one remaining stack structure.

In operation S530, as illustrated in FIG. 6H, the manufacturing system may stack the remaining stack structure USS on the at least one stack structure LSS or MSS. Although not illustrated in a separate drawing, the manufacturing system may, before operation S530, planarize an upper surface of the capping layer CL of the at least one stack structure LSS or MSS so that another stack structure may be smoothly stacked on the at least one stack structure LSS or MSS.

In operation S540, as illustrated in FIG. 6I, the manufacturing system may form the channel holes CH on the remaining stack structure USS, and at the same time, remove the capping film “C” of the at least one stack structure LSS or MSS. In more detail, the manufacturing system may etch and form the channel holes CH on the remaining stack structure USS, at the same time, may etch the capping film “C” of the at least one stack structure LSS and MSS together, and thus may connect the channel holes CH of the remaining stack structure USS and the channel holes CH of the at least one stack structure LSS or MSS to each other.

In this way, in the process of forming the channel holes CH of the remaining stack structure USS, the capping film “C” having a size that is smaller than the size of each of the channel holes CH of the at least one stack structure LSS or MSS on a plane is removed, and the channel holes CH of the remaining stack structure USS and the channel holes CH of the at least one stack structure LSS or MSS are connected to each other. Thus, an etching profile of the channel holes CH of the at least one stack structure LSS or MSS and an etching profile of the channel holes CH of the remaining stack structure USS may be uniformly maintained.

In operation S550, as illustrated in FIG. 6J, the manufacturing system may form the vertical channel structures VS in the channel holes CH of a semiconductor structure SEMI-STR in which the at least one stack structure LSS or MSS and the remaining stack structure USS are stacked. In detail, operation S550 may include a first operation of forming the data storage pattern DSP on the inner walls of the channel holes CH and a second operation of forming the vertical channel pattern VCP on the inner wall of the data storage pattern DSP (when the vertical semiconductor pattern VSP is included, the vertical semiconductor pattern VSP is also formed together with the vertical channel pattern VCP).

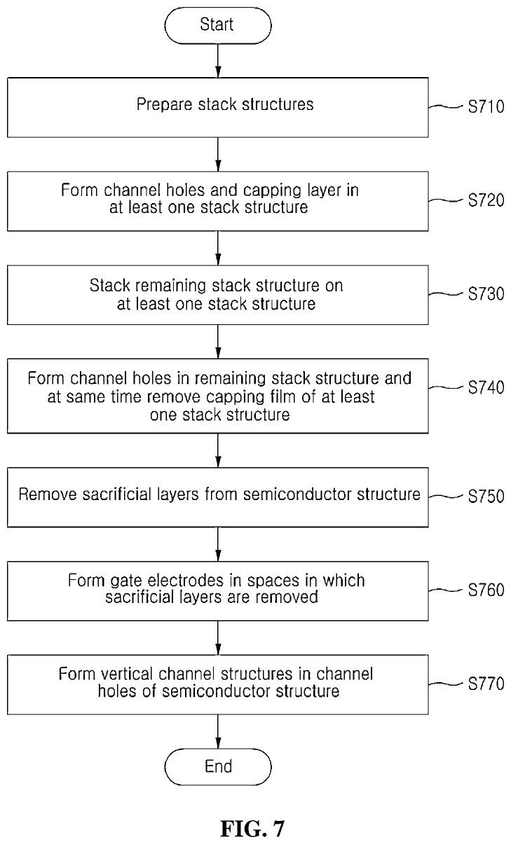

FIG. 7 is a flowchart illustrating the method of manufacturing the three-dimensional flash memory according to the embodiment in which a word line replacement method is applied to manufacture the three-dimensional flash memory illustrated in FIGS. 2 to 3, and FIGS. 8A to 8L are cross-sectional views illustrating the structure of the three-dimensional flash memory to describe the method of manufacturing the three-dimensional flash memory illustrated in FIG. 7.

Hereinafter, the method of manufacturing the three-dimensional flash memory according to the embodiment is intended to manufacture the three-dimensional flash memory having the structure described with reference to FIGS. 2 to 4 by applying the word line replacement method, and it is assumed that the method is performed by an automated and mechanized manufacturing system.

Further, hereinafter, for convenience of description, the manufacturing method is described as manufacturing the three-dimensional flash memory having a structure including the interlayer insulating films ILD, the word lines WL0 to WLn, the vertical channel structures VS, and the capping layer CL. Because the materials constituting the components of the three-dimensional flash memory have been described with reference to FIGS. 2 to 4, a detailed description thereof will be omitted.

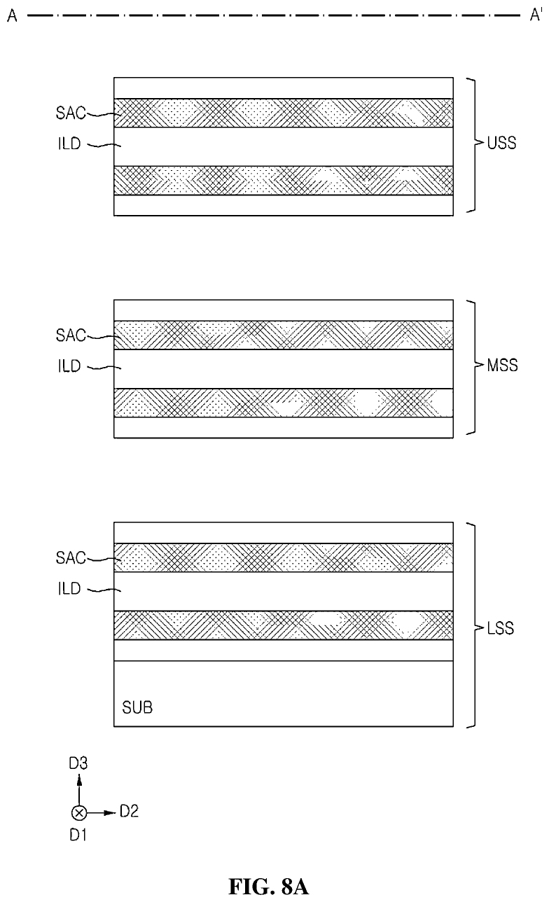

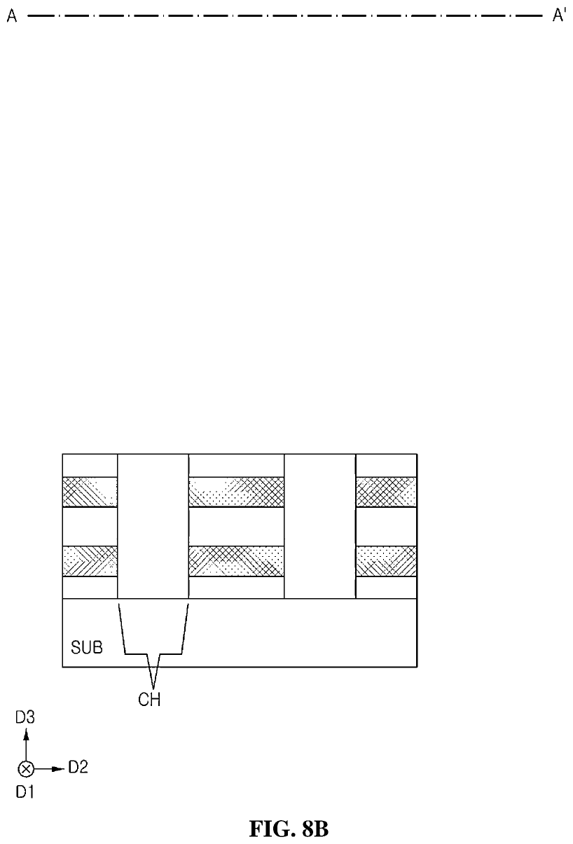

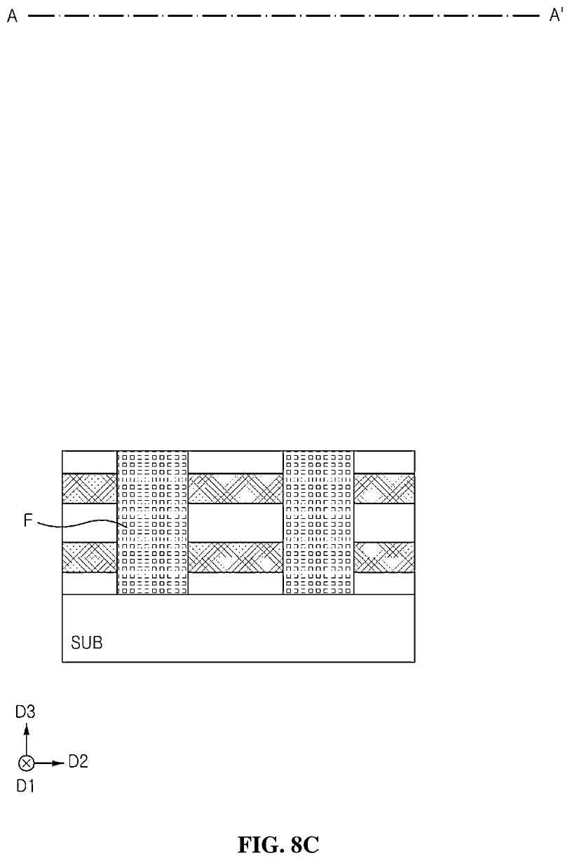

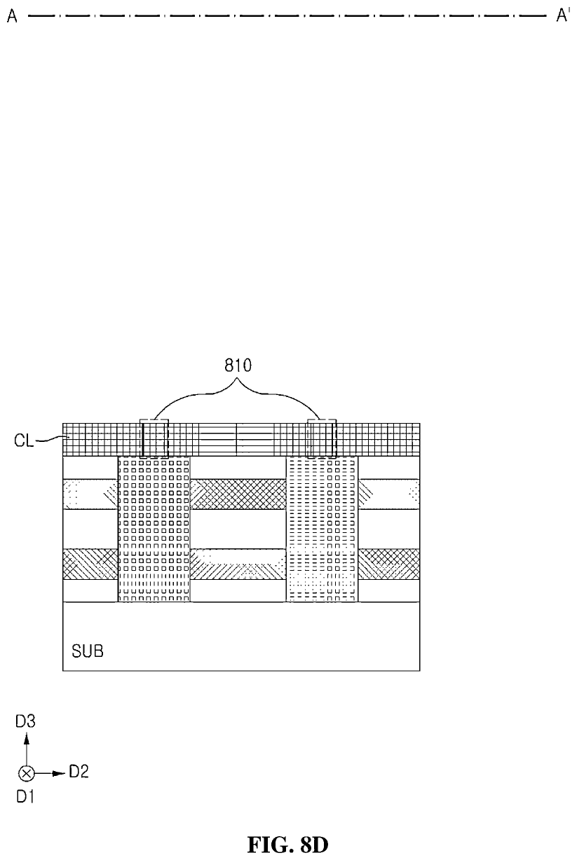

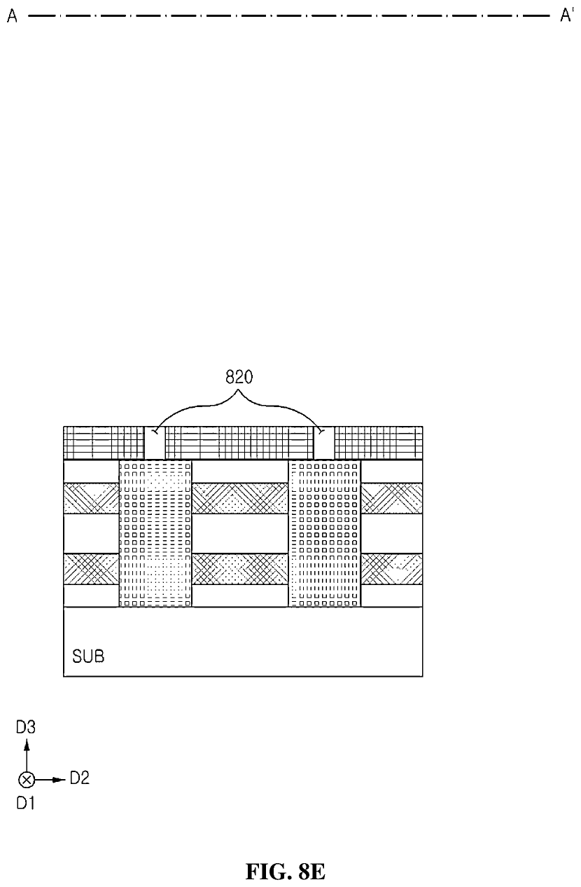

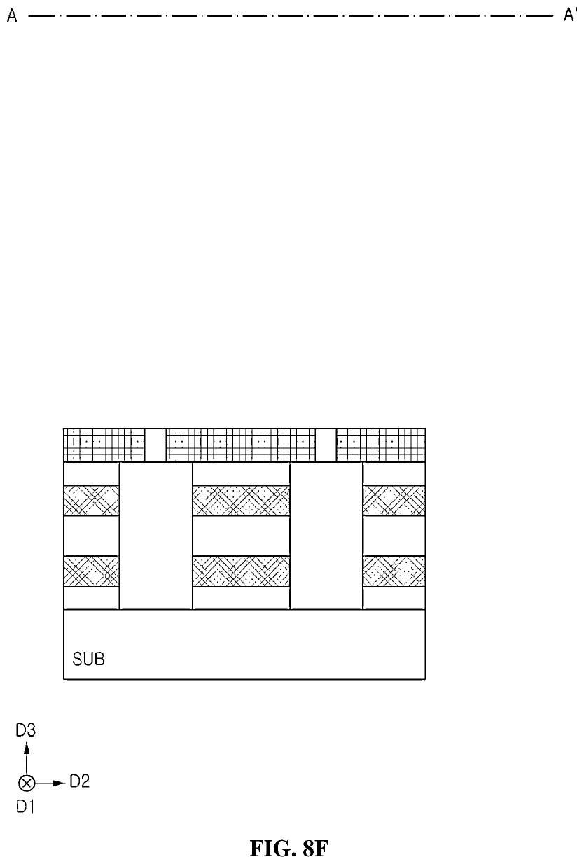

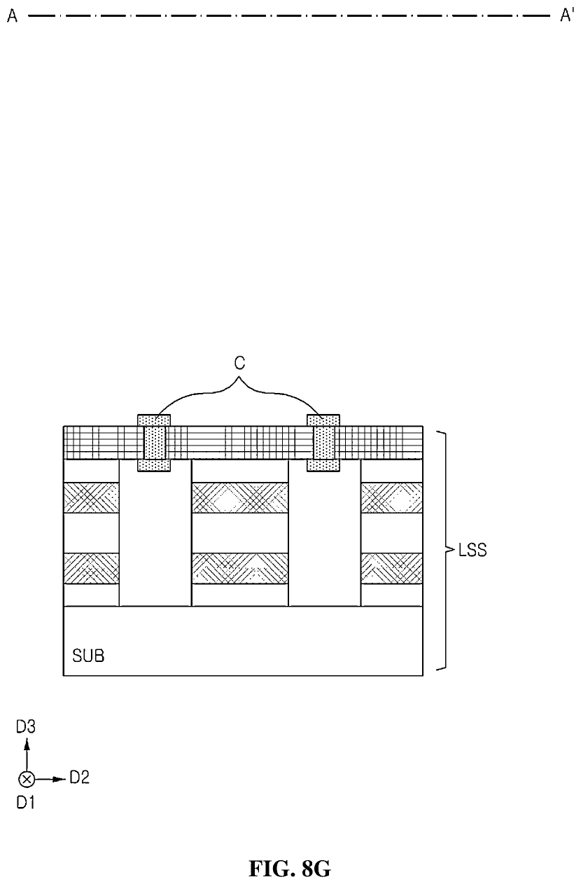

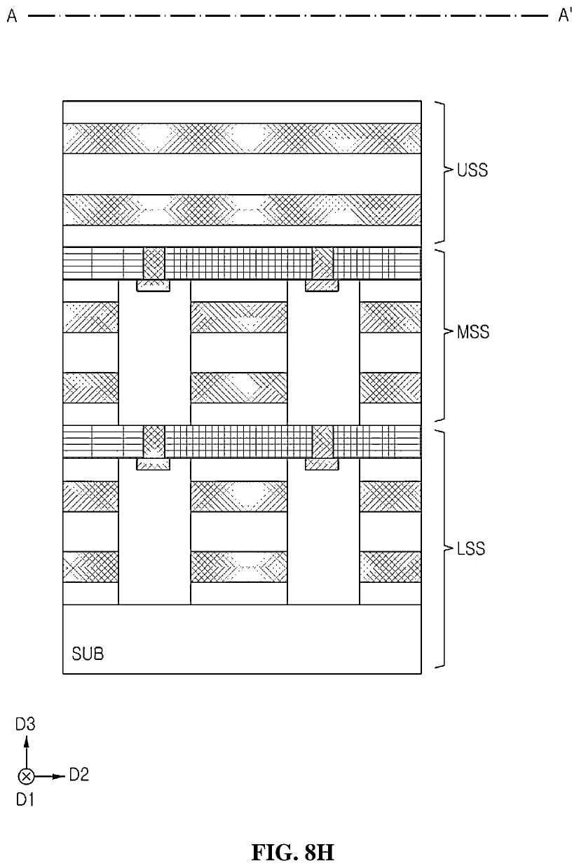

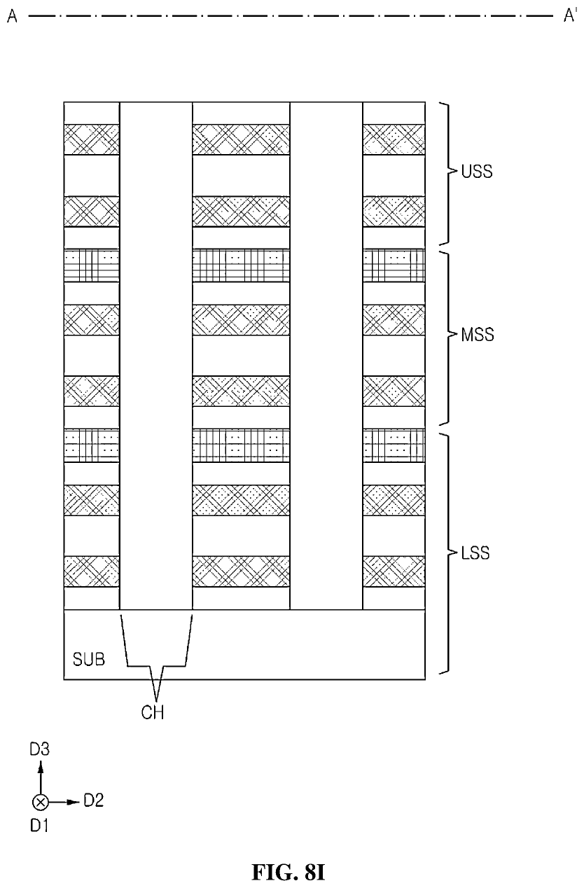

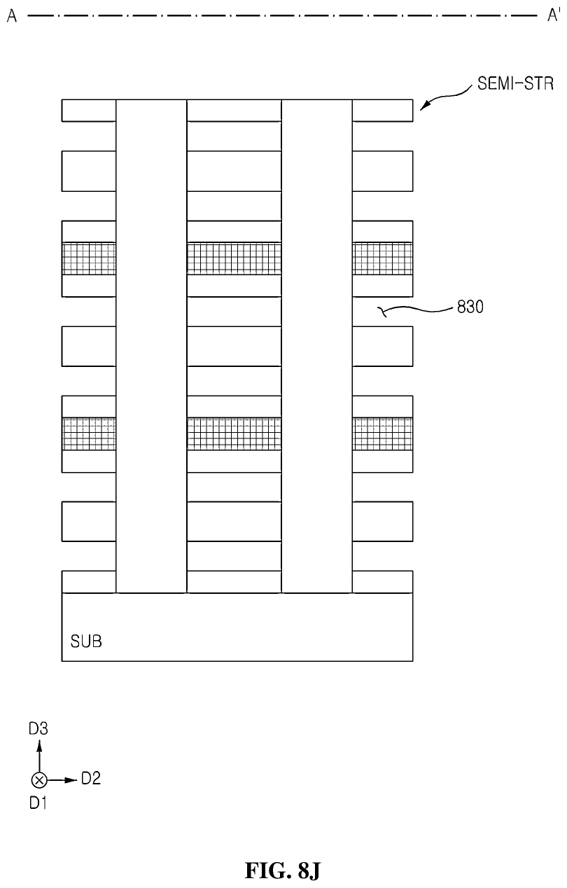

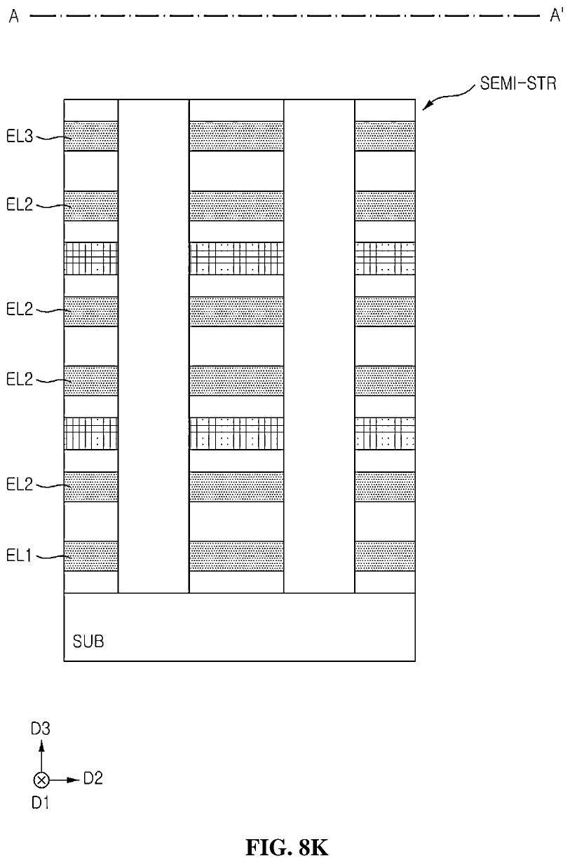

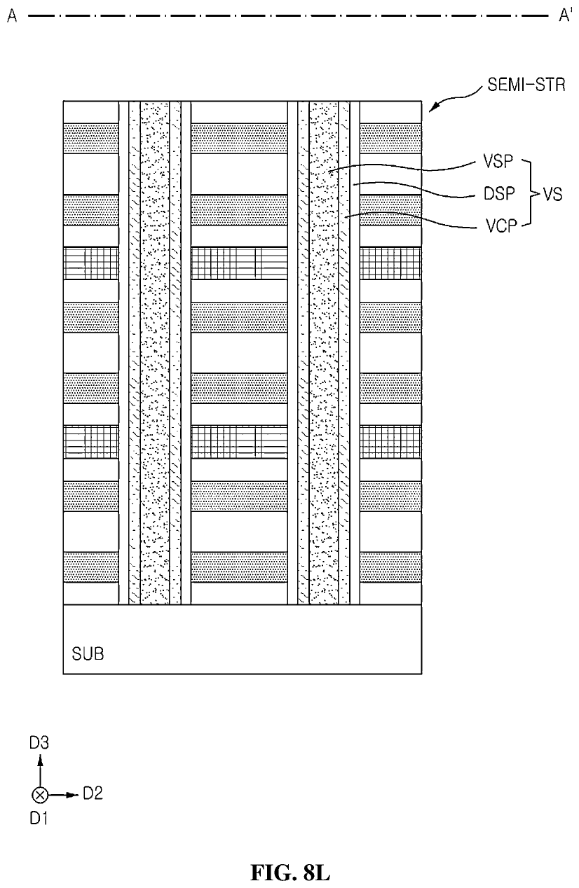

Referring to FIG. 7, in operation S710, as illustrated in FIG. 8A, the manufacturing system may prepare the stack structures USS, MSS, and LSS including the interlayer insulating films ILD and sacrificial layers SAC formed to extend in the horizontal direction and alternately stacked in the vertical direction (e.g., the third direction D3).

In operation S720, as illustrated in FIGS. 8B to 8G, the manufacturing system may form the capping layer CL including the channel holes CH and the capping film “C” in at least one stack structure LSS among the stack structures USS, MSS, and LSS.

In more detail, the manufacturing system may form the channel holes CH in the at least one stack structure LSS as illustrated in FIG. 8B, form the filling film “F” in the channel holes CH as illustrated in FIG. 8C, form the capping layer CL on the at least one stack structure LSS on which the filling film “F” is formed as illustrated in FIG. 8D, etch a partial area 810 of the capping layer CL as illustrated in FIG. 8E, remove the filling film “F” through a space 820 in which the partial area 810 of the capping layer CL is etched as illustrated in FIG. 8F, and thus form the capping film “C” in the space 820 in which the partial area 810 of the capping layer CL is etched as illustrated in FIG. 8G.

In this case, because the etched partial area 810 of the capping layer CL has a size that is smaller than a size of each of the channel holes CH included in the at least one stack structure LSS on a plane, the capping film “C” formed in the space 820 in which the partial area 810 of the capping layer CL is etched may also have a size that is smaller than the size of each of the channel holes CH included in the at least one stack structure LSS on a plane. That is, as illustrated in FIG. 8G, the forming of the capping film “C” in the space 820 in which the partial area 810 of the capping layer CL is etched may mean forming of the capping film “C” having the size that is smaller than the size of each of the channel holes CH included in the at least one stack structure LSS on a plane.

In this way, the capping film “C” may be formed on the capping layer CL to have the size that is smaller than the size of each of the channel holes CH included in the at least one stack structure LSS on a plane, thus may be removed in a process of etching the channel holes CH in the remaining stack structure USS, and may connect the channel holes CH of the remaining stack structure USS to the channel holes CH of the at least one stack structure LSS.

Here, a process of etching the partial area 810 of the capping layer CL may be performed so that a profile of the space 820 in which the partial area 810 of the capping layer CL is etched is various. For example, as illustrated in FIG. 8E, the manufacturing system may perform an etching process on the partial area 810 of the capping layer CL such that the space 820 in which the partial area 810 of the capping layer CL is etched has a uniform profile in the vertical direction. As another example, the manufacturing system may perform an etching process on the partial area 810 of the capping layer CL such that the space 820 in which the partial area 810 of the capping layer CL is etched has a negative profile or a positive profile in the vertical direction.

Further, as illustrated in FIG. 8C, the filling film “F” formed in the channel holes CH may be formed of a material that may be removed through the space 820 from which the partial area 810 of the capping layer CL having the size that is smaller than the size of each of the channel holes CH included in the at least one stack structure LSS on a plane is removed.

Further, the manufacturing system may perform operation S720 for at least one stack structure MSS.

Hereinafter, since a case in which the manufacturing system manufactures the three-dimensional flash memory by stacking the three stack structures LSS, MSS, and USS has been described, operation S720 is performed on the two stack structures LSS and MSS. However, when the three-dimensional flash memory is manufactured by stacking four or more stack structures, operation S720 may be performed on all the remaining stack structures except for one remaining stack structure.

In operation S730, as illustrated in FIG. 8H, the manufacturing system may stack the remaining stack structure USS on the at least one stack structure LSS or MSS. Although not illustrated in a separate drawing, the manufacturing system may, before operation S730, planarize an upper surface of the capping layer CL of the at least one stack structure LSS or MSS so that another stack structure may be smoothly stacked on the at least one stack structure LSS or MSS.

In operation S740, as illustrated in FIG. 8I, the manufacturing system may form the channel holes CH on the remaining stack structure USS, and at the same time, remove the capping film “C” of the at least one stack structure LSS or MSS. In more detail, the manufacturing system may etch and form the channel holes CH on the remaining stack structure USS, at the same time, may etch the capping film “C” of the at least one stack structure LSS and MSS together, and thus may connect the channel holes CH of the remaining stack structure USS and the channel holes CH of the at least one stack structure LSS or MSS to each other.

In this way, in the process of forming the channel holes CH of the remaining stack structure USS, the capping film “C” having a size that is smaller than the size of each of the channel holes CH of the at least one stack structure LSS or MSS on a plane is removed, and the channel holes CH of the remaining stack structure USS and the channel holes CH of the at least one stack structure LSS or MSS are connected to each other. Thus, the etching profile of the channel holes CH of the at least one stack structure LSS or MSS and the etching profile of the channel holes CH of the remaining stack structure USS may be uniformly maintained.

In operation S750, as illustrated in FIG. 8J, the manufacturing system may remove the sacrificial layers SAC from the semiconductor structure SEMI-STR in which the at least one stack structure LSS or MSS and the remaining stack structure USS are stacked. In this case, the channel holes CH of the semiconductor structure SEMI-STR may be used as a passage through which the sacrificial layer SAC is removed, but the present disclosure is not limited thereto, and a separate trench (not illustrated) formed in the semiconductor structure SEMI-STR may be used as the passage.

In operation S760, as illustrated in FIG. 8K, the manufacturing system may form the gate electrodes EL1 to EL3 in spaces 830 from which the sacrificial layers SAC are removed.

In operation S770, as illustrated in FIG. 8L, the manufacturing system may form the vertical channel structures VS in the channel holes CH of the semiconductor structure SEMI-STR. In detail, operation S770 may include a first operation of forming the data storage pattern DSP on the inner walls of the channel holes CH and a second operation of forming the vertical channel pattern VCP on the inner wall of the data storage pattern DSP (when the vertical semiconductor pattern VSP is included, the vertical semiconductor pattern VSP is also formed together with the vertical channel pattern VCP).

As described above, although the embodiments have been described with reference to the limited embodiments and the limited drawings, various modifications and changes may be made based on the above description by those skilled in the art. For example, even though the described technologies are performed in an order different from the described method, and/or the described components such as a system, a structure, a device, and a circuit are coupled or combined in a form different from the described method or are replaced or substituted by other components or equivalents, appropriate results may be achieved.

Therefore, other implementations, other embodiments, and those equivalent to the appended claims also belong to the scope of the appended claims.

1. A method of manufacturing a three-dimensional flash memory, the method comprising:
preparing stack structures including interlayer insulating films and gate electrodes formed to extend in a horizontal direction and alternately stacked in a vertical direction;
forming channel holes and a capping layer including a capping film in at least one stack structure among the stack structures;
stacking a remaining stack structure on the at least one stack structure;
forming channel holes in the remaining stack structure, and at the same time, removing the capping film of the at least one stack structure; and
forming vertical channel structures in channel holes of a semiconductor structure in which the at least one stack structure and the remaining stack structure are stacked.

2. The method of claim 1, wherein the capping film is formed on the capping layer to have a size that is smaller than a size of each of the channel holes on a plane.

3. The method of claim 2, wherein the forming of the channel holes and the capping layer including the capping film in the at least one stack structure includes:
forming the channel holes in the at least one stack structure;
forming a filling film in the channel holes;
forming the capping layer on the at least one stack structure in which the filling film is formed;
etching a partial area of the capping layer, the partial area having the size that is smaller than the size of each of the channel holes on a plane;
removing the filling film through a space in which the partial area of the capping layer is etched; and
forming the capping film in the space in which the partial area of the capping layer is etched such that the capping film has the size that is smaller than the size of each of the channel holes on a plane.

4. The method of claim 3, wherein the etching of the partial area of the capping layer includes:
etching the partial area such that the space in which the partial area of the capping layer is etched has a negative profile, a positive profile, or a uniform profile.

5. The method of claim 3, wherein the forming of the filling film includes:
forming the filling film with a material removable through the space in which the partial area of the capping layer having the size that is smaller than the size of each of the channel holes on a plane is etched.

6. A method of manufacturing a three-dimensional flash memory, the method comprising:
preparing stack structures including interlayer insulating films and sacrificial layers formed to extend in a horizontal direction and alternately stacked in a vertical direction;
forming channel holes and a capping layer including a capping film in at least one stack structure among the stack structures;
stacking a remaining stack structure on the at least one stack structure;
forming channel holes in the remaining stack structure, and at the same time, removing the capping film of the at least one stack structure;
removing the sacrificial layers from a semiconductor structure in which the at least one stack structure and the remaining stack structure are stacked;
forming gate electrodes in spaces in which the sacrificial layers are removed; and
forming vertical channel structures in the channel holes of the semiconductor structure.

7. The method of claim 6, wherein the capping film is formed on the capping layer to have a size that is smaller than a size of each of the channel holes on a plane.

8. The method of claim 7, wherein the forming of the channel holes and the capping layer including the capping film in the at least one stack structure includes:
forming the channel holes in the at least one stack structure;
forming a filling film in the channel holes;
forming the capping layer on the at least one stack structure in which the filling film is formed;
etching a partial area of the capping layer, the partial area having the size that is smaller than the size of each of the channel holes on a plane;
removing the filling film through a space in which the partial area of the capping layer is etched; and
forming the capping film in the space in which the partial area of the capping layer is etched such that the capping film has the size that is smaller than the size of each of the channel holes on a plane.

9. The method of claim 8, wherein the etching of the partial area of the capping layer includes:
etching the partial area such that the space in which the partial area of the capping layer is etched has a negative profile, a positive profile, or a uniform profile.

10. The method of claim 8, wherein the forming of the filling film includes:
forming the filling film with a material removable through the space in which the partial area of the capping layer having the size that is smaller than the size of each of the channel holes on a plane is etched.

11. A three-dimensional flash memory comprising:
stack structures including interlayer insulating films and gate electrodes formed to extend in a horizontal direction and alternately stacked in a vertical direction and vertical channel structures formed to extend in the vertical direction while passing through the interlayer insulating films and the gate electrodes, the stack structures being stacked in the vertical direction; and
a capping layer connecting the vertical channel structures of the stack structures to each other such that an etching profile of the vertical channel structures of the stack structures is uniformly maintained while being disposed between the stack structures.

12. The three-dimensional flash memory of claim 11, wherein the capping layer includes a capping film having a size that is smaller than a size of each of channel holes included in each of the stack structures on a plane, connects the channel holes to each other as the capping film is removed in a process of etching the channel holes, and thus connects the vertical channel structures to each other while the etching profile of the vertical channel structures is uniformly maintained.
